(19) United States
(12) Patent Application Publication
(10) Pub. No.: US 2012/0187971 A1
(43) Pub. Date: Jul. 26, 2012

(54) HIGH-FREQUENCY VERTICAL SPRING PROBE CARD STRUCTURE

(75) Inventor: Cheng-Lung Huang, Hsinchu County (TW)

(73) Assignee: PLeader-YAMAICHI Co., Ltd, Hsinchu City (TW)

(21) Appl. No.: 13/343,712

(22) Filed: Jan. 5, 2012

(30) Foreign Application Priority Data
Jan. 20, 2011 (TW) 100102083

(51) Int. Cl. G01R 1/067

(52) U.S. Cl. 324/755.05

(57) ABSTRACT

The invention provides a high-frequency vertical spring probe card structure including a plurality of probes. Each of the probes includes at least one conducting layer and at least one insulating layer. The conducting layer includes a first contact end and a second contact end used for electrically contacting an external component while the probe is compressed and includes a probe body including at least one plate portion and at least one resilient portion connected to each other. The plate portion is used for supporting deformation of the resilient portion while the resilient portion is compressed vertically. The insulating layer includes at least one plate member tightly attached to the plate portion of the conducting layer correspondingly. The probe structure of the invention is simple and can be formed as multi-layer stack structure by electroplating through Lithographie GaVanoformung Abformung (LIGA) technology.

### BACKGROUND OF THE INVENTION

1. Field of the Invention

The invention relates to a probe structure and, more particularly, to a high-frequency vertical spring probe card structure, which is a new design of micro probe structure and can be used for testing high-frequency and high-speed chip. The probe of the invention can maintain good contact status during testing when the probe is compressed vertically.

2. Description of the Prior Art

In semiconductor industry, a die of a chip has to be tested by probes through related testing instrument and software before package so as to sieve good products and bad products. Afterward, the good products are delivered to package process.

Since integrated circuit process advances continuously, line width and pitch between circuits are getting smaller and smaller. The probe for testing is changed from a horizontal cantilever-type probe with curved tip to a vertical probe with small diameter. The vertical probes can be arranged tightly and the pitch between two vertical probes is narrow. Referring to FIG. 1, FIG. 1 is a schematic diagram illustrating a conventional vertical probe structure. As shown in FIG. 1, the conventional probe 90 is a spring-type probe formed by machining process. The conventional probe 90 consists of a sleeve 91, a contact end 92, a shaft 93 and a spring 94. The contact end 92 is used for contacting an object (e.g. die) for electrical testing. The other end opposite to the contact end 92 contacts a circuit board. The spring 94 is wound around a periphery of the shaft 93 so as to enhance elasticity of the probe 90. Then, the assembly of the shaft 93 and the spring 94 is disposed in the sleeve 91 so as to complete complicated assembly process of the conventional probe 90.

However, the aforesaid conventional probe still has lots of disadvantages. First, it requires much time and work to assemble each probe by labor and the cost increases accordingly. Furthermore, since the contact end of the aforesaid probe has a column shape, testing stability will be influenced if the evenness of the contact end is bad. Still further, it is difficult to manufacture and assemble a great quantity of conventional probes due to limitation of the shape and the pitch between two probes cannot be reduced. Moreover, parts of the aforesaid are exposed without insulation, so it may generate additional capacitance and inductance easily and is not suitable for high-frequency testing. Therefore, the invention provides a high-frequency vertical spring probe card structure to solve the aforesaid problems.

### SUMMARY OF THE INVENTION

An objective of the invention is to provide a high-frequency vertical spring probe card structure, which is a new design of micro probe structure and can be used for testing high-frequency and high-speed chip.

Another objective of the invention is to provide a high-frequency vertical spring probe card structure, which can be formed as a multi-layer probe by Micro-Electro-Mechanical System (MEMS) process or formed by Lithographie GaVanoformung Abformung (LIGA) technology rapidly and simply.

Another objective of the invention is to provide a high-frequency vertical spring probe card structure, wherein a probe body has non-uniform elasticity from top to bottom. The invention determines the configuration of the probe according to the acting force applied to the probe. Accordingly, the maximum deformation of the probe can be increased by simple design.

To achieve the aforesaid objectives, the invention provides a high-frequency vertical spring probe card structure comprising a plurality of probes. Each of the probes comprises at least one conducting layer and at least one insulating layer. The conducting layer comprises a first contact end and a second contact end used for electrically contacting an external component while the probe is compressed and comprises a probe body comprising at least one plate portion and at least one resilient portion connected to each other. The plate portion is used for supporting deformation of the resilient portion while the resilient portion is compressed vertically. The insulating layer comprises at least one plate member tightly attached to the plate portion of the conducting layer correspondingly.

The high-frequency vertical spring probe card structure of the invention has following advantages:

1) The high-frequency vertical spring probe card structure can be manufactured by advanced process (e.g. LIGA process, etc.) so as to form multi-layer probe. Compared to conventional machining process, the invention can save much time and cost.

2) According to the aforesaid advantage, the multi-layer probe manufactured by advanced process has better evenness than the conventional probe, so it can increase testing stability. However, the conventional machining process cannot guarantee that all conventional probes can contact corresponding contact points stably.

3) The lateral shape of the high-frequency vertical spring probe card structure is flatter than that of the conventional probe, so more probes can be installed on the probe card of the invention. Furthermore, the pitch between two probe tips is also smaller than that of the conventional probe such that the invention can satisfy a great quantity of probes needed by industry.

4) The high-frequency vertical spring probe card structure further has the insulating layer except the conductive layer. Compared to the conventional probe without insulation, the invention will not generate additional capacitance and inductance, can improve signal strength, and can reduce audio stream. Therefore, the high-frequency vertical spring probe card structure can be applied to high-frequency testing.

5) The high-frequency vertical spring probe card structure may use two probes to contact one single solder ball and the design of the other end can increase the pitch. The upper contact ends contact different circuit boards so as to achieve effects of withstanding current and withstanding voltage and reduce signal interference. Consequently, the invention can achieve precision measurement and enhance testing current and power range of chip.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a conventional vertical probe structure.

FIG. 2 is a schematic assembly diagram illustrating a probe structure according to a first embodiment of the invention.

FIG. 3 is a schematic exploded diagram illustrating the probe structure according to the first embodiment of the invention.

FIG. 4 is a schematic assembly diagram illustrating a multi-layer probe structure according to a second embodiment of the invention.

FIG. 5 is a schematic exploded diagram illustrating the multi-layer probe structure according to the second embodiment of the invention.

FIG. 6 is a schematic cross-sectional diagram illustrating the probe of the first embodiment being used.

FIG. 7A is a schematic diagram illustrating a first type of the resilient portion of the invention.

FIG. 7B is a schematic diagram illustrating a second type of the resilient portion of the invention.

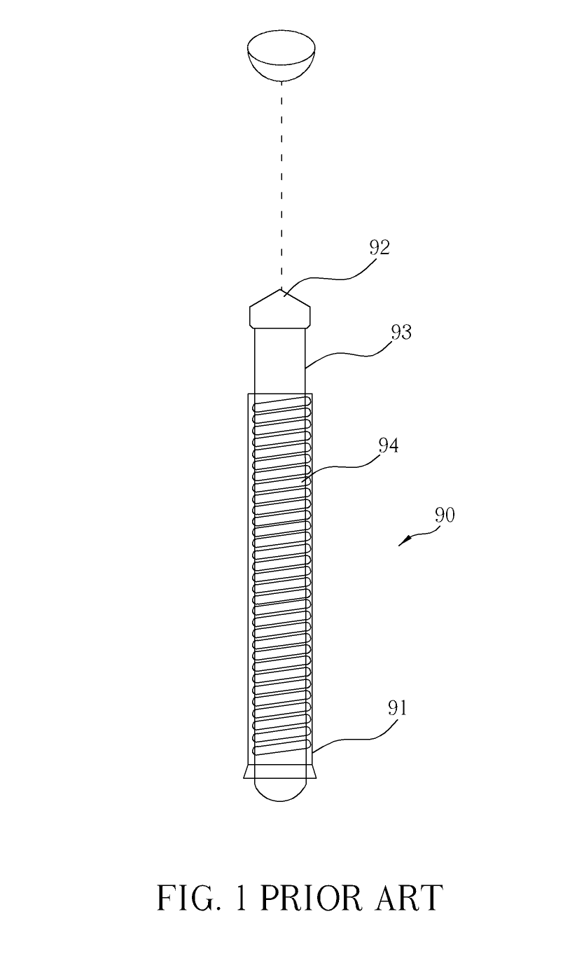

### DETAILED DESCRIPTION

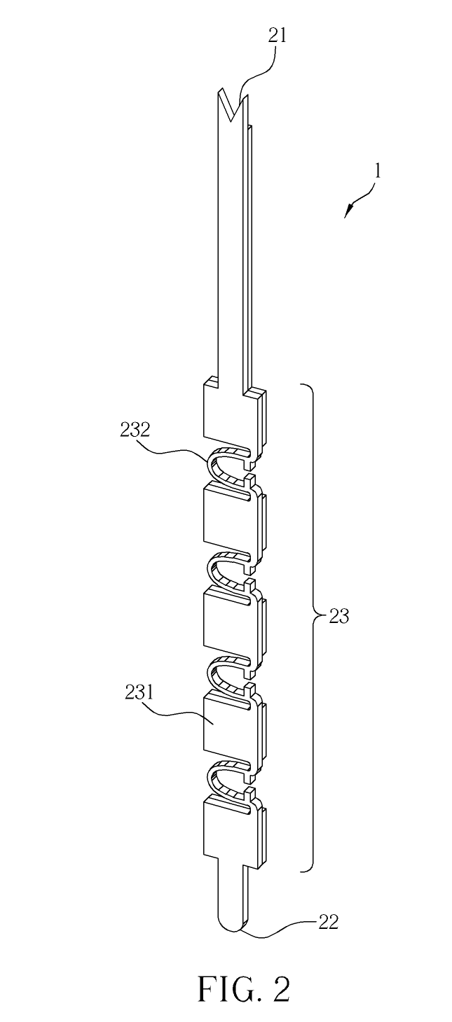

Referring to FIG. 2, FIG. 2 is a schematic assembly diagram illustrating a probe structure according to a first embodiment of the invention. The probe 1 of the invention comprises a first contact end 21, a second contact end 22 and a probe body 23. The first contact end 21 and the second contact end 22 are used for electrically contacting an external component while the probe 1 is compressed. The probe body 23 comprises a plurality of plate portions 231 and a plurality of resilient portions 232, wherein the plate portions 231 and the resilient portions 232 are connected to each other. The plate portions 231 are used for supporting deformation of the resilient portions 232 while the resilient portions 232 are compressed vertically. Furthermore, the probe 1 is flat so a plurality of probes 1 can be arranged in parallel with lateral surface (i.e. the smaller surface of the probe) . Therefore, the invention can dispose more and more probes 1 on testing components or circuit boards with the same area by the aforesaid parallel arrangement so as to satisfy a great quantity of probes needed by probe testing device.

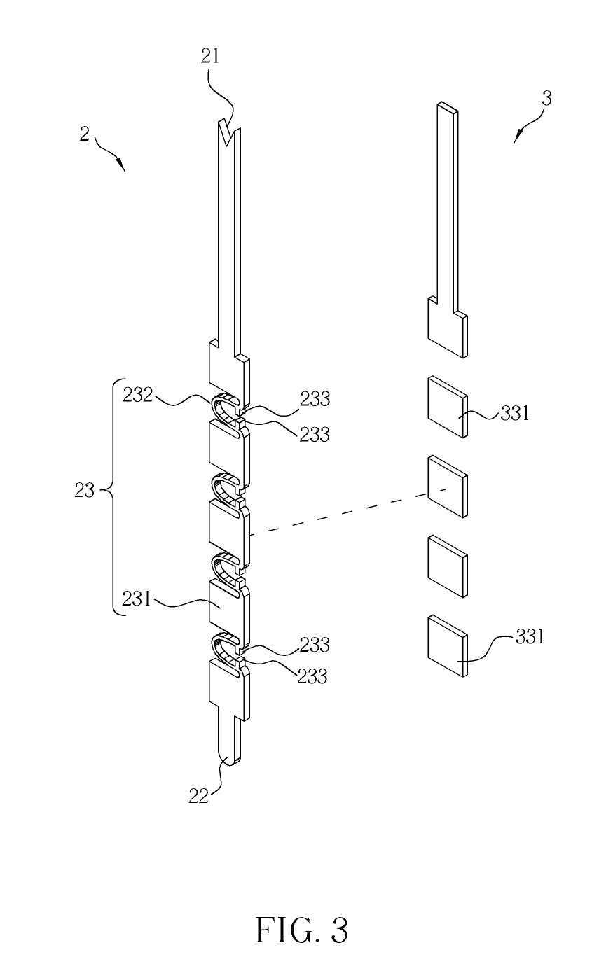

Referring to FIG. 3, FIG. 3 is a schematic exploded diagram illustrating the probe structure according to the first embodiment of the invention. In this embodiment, the aforesaid probe will be depicted in detail. The probe (not labeled in FIG. 3) comprises a conducting layer 2 and an insulating layer 3. The conducting layer 2 is made of conductive material, such as conductive metal, conductive alloy or the like. The insulating layer 3 is made of non-conductive material, such as electrical insulation material or the like. The conducting layer 2 and the insulating layer 3 may be formed by electroplating through Lithographie GaVanoformung Abformung (LIGA) technology or formed as a multi-layer micro-probe by Micro-Electro-Mechanical System (MEMS) process. The conducting layer 2 and the insulating layer 3 of each probe are separated by each other. The probe body 23 of the conducting layer 2 comprises a plurality of plate portions 231 corresponding to a plurality of plate members 331 of the insulating layer 3. Once the probe is compressed, the plate portions 231 and the plate members 331 can support deformation of the resilient portions 232 and reinforce elasticity of the resilient portions 232 so as to prevent the probe from fracturing due to great deformation. Furthermore, the resilient portion 232 may further has at least one force restricting protrusion 233 for preventing or restricting the probe from fracturing once the resilient portion 232 is over-compressed. When the probe is compressed vertically, the resilient portion 232 is bended due to compression. Once the resilient portion 232 is over-compressed, the force restricting protrusion 233 will contact the opposite force restricting protrusion 233. At this time, the resilient portion 232 has been bended to the maximum deformation and is restricted by the force restricting protrusion 233 such that the probe is not compressed anymore so as to prevent the resilient portion 232 from fracturing due to over-compression. As mentioned in the above, since the probe body 23 has the resilient portion 232, the plate portion 231 and the force restricting protrusion 233, the life span of the probe can be extended effectively.

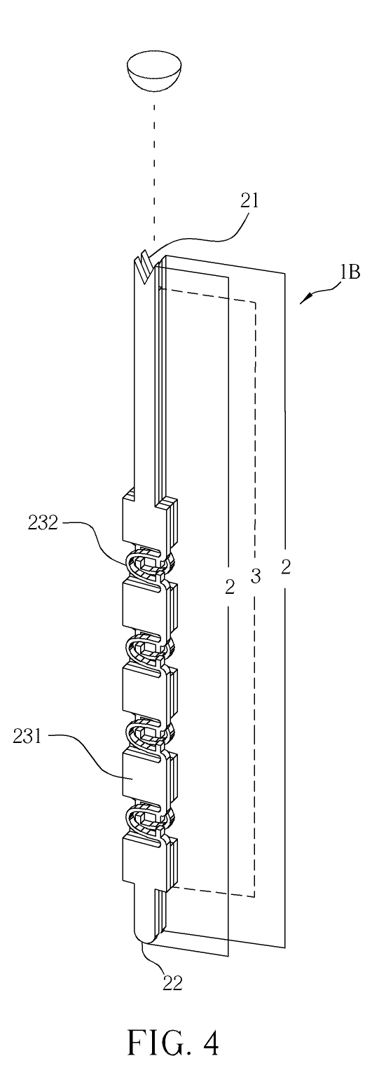

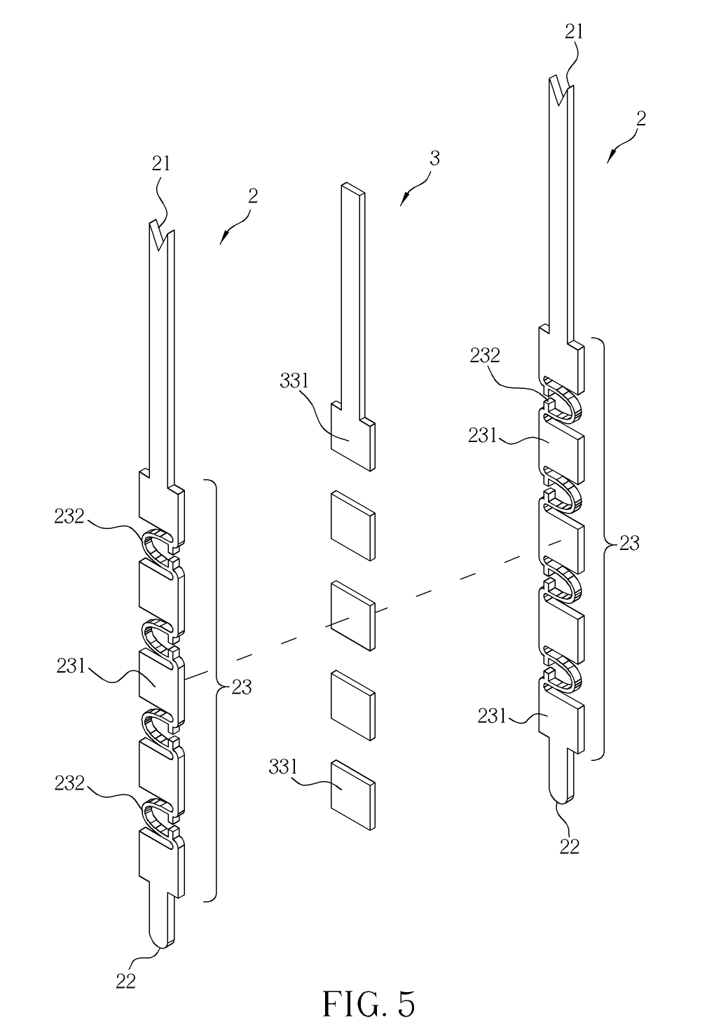

Besides the aforesaid first embodiment, the invention also provides a multi-layer stack probe for different testing devices. Referring to FIGS. 4 and 5, FIG. 4 is a schematic assembly diagram illustrating a multi-layer probe structure according to a second embodiment of the invention, and FIG. 5 is a schematic exploded diagram illustrating the multi-layer probe structure according to the second embodiment of the invention. The second embodiment is for multi-layer stack probe. As shown in FIG. 4, the conducting layer 2 and the insulating layer 3 of the probe 1B are separated by each other and can be formed in the following order of conducting layer 2, insulating layer 3, conducting layer 2, and so on. The number of layers can be increased or decreased according to testing requirement. Each of the conducting layers 2 comprises a plurality of plate portions 231 and a plurality of resilient portions 232, wherein the plate portions 231 and the resilient portions 232 are connected to each other. Each of the insulating layers 3 also comprises a plurality of plate members 331, as shown in FIG. 5. Furthermore, the aforesaid flat probes 1 can be arranged in parallel so as to reduce the pitch between every two probe tips such that the space within limit range can be utilized effectively to accommodate more probes 1. Accordingly, the multi-layer probe 1B may has a plurality of contact tips (i.e. first contact end 21) contacting one single solder ball. The principle of the second embodiment is the same as that of the first embodiment and the related explanation will not be depicted herein again. FIG. 4 shows a probe with three layers. Each of the probes can be formed by stacking and staggering a plurality of conducting layers 2 and a plurality of insulating layers 3. The multi-layer stack probe shown in FIG. 4 is one embodiment of the invention and the scope of the invention is not limited to this embodiment.

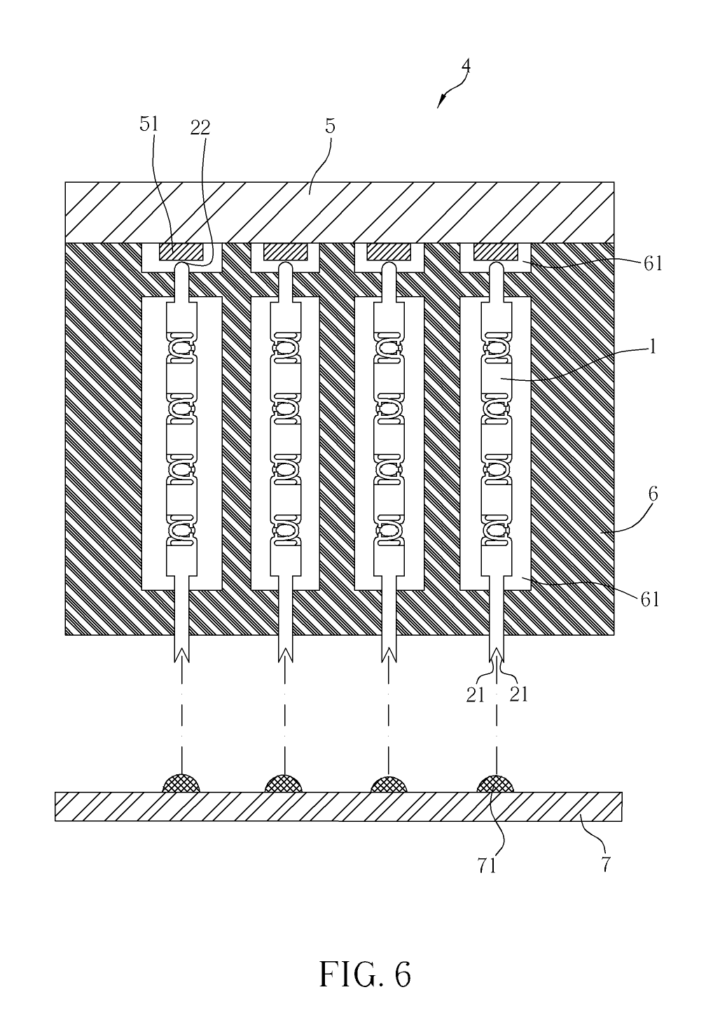

Referring to FIG. 6, FIG. 6 is a schematic cross-sectional diagram illustrating the probe of the first embodiment being used. The probe card 4 comprises a circuit board 5, a fixing component 6 and a plurality of probes 1. The circuit board 5 connects the fixing component 6 and the signal metal pad 51. A plurality of accommodating spaces 61 is formed in the fixing component 6 and below the circuit board 5. The probe 1 is accommodated in the accommodating space 61. The probe 1 is fixed in the probe card 4 by the fixing component 6. Due to the fixing component 6, the probes 1 can be only compressed vertically and cannot move laterally or in other directions. When the probe 1 is fixed, the second contact end 22 electrically contacts the signal metal pad 51 such that the probe is electrically connected to the circuit board 5. During testing, the probe card 4 moves over a testing machine. When the probe 1 of the probe card 4 gets close to a testing component 7 (e.g. chip or circuit board), the first contact end 21 of the probe 1 electrically contacts the solder ball 71 on the testing component 7 so as to determine the quality of the testing component 7. The circuit board 5 and the fixing component 6 can be connected to each other by screwing device or other auxiliary fixing device such that the invention can be applied to a probe card product. The probe 1 of the invention can be applied to many products. The aforesaid embodiment is used for illustration purpose only and the scope of the invention is not limited to the embodiment.

The probe 1 of the invention is not limited to use the first contact end 21 to contact the solder ball 71 of the testing component 7. In other words, the probe 1 can be also installed in the fixing component 6 inversely so as to use the second contact end 22 to contact the solder ball 71 of the testing component 7. Furthermore, the probe of the invention can be also installed between two circuit boards for purpose of electric and signal transmission. Moreover, though the contact tip (i.e. the first contact end 21) of the invention is formed as V-shape, the contact tip is not limited to V-shape and the shape of the contact tip can be determined based on practical applications. It should be noted that the contact tip has to provide good contact status and stable signal transmission while the probe electrically contacts the external component no matter what the shape of the contact tip is. The number of the first contact end 21 and the second contact end 22 is not limited to one and it can be determined based on the number of stack layers.

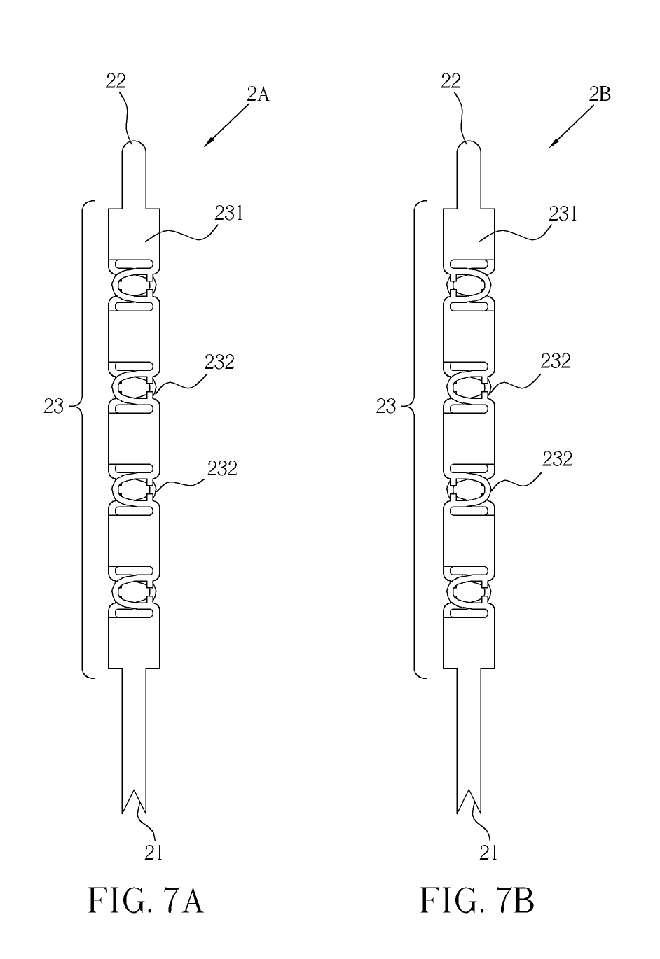

Referring to FIGS. 7A and 7B, FIG. 7A is a schematic diagram illustrating a first type of the resilient portion of the invention, and FIG. 7B is a schematic diagram illustrating a second type of the resilient portion of the invention. The resilient portion 232 of the conducting layer 2A is curved and FIG. 7A only shows one embodiment of the invention. As shown in FIG. 7A, the resilient portions 232 may be curved in the same direction. As shown in FIG. 7B, the resilient portions 232 may be curved in different directions. The type of the resilient portion 232 can be adjusted according to the force applied to the contact tip. Accordingly, the resilient portion 232 can support great force and acting force without deformation.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high-frequency vertical spring probe card structure comprising
a plurality of probes, each of the probes comprising:
at least one conducting layer comprising:
a first contact end and a second contact end used for electrically contacting an external component while the probe is compressed; and
a probe body comprising at least one plate portion and at least one resilient portion connected to each other, the plate portion being used for supporting deformation of the resilient portion while the resilient portion is compressed vertically; and
at least one insulating layer comprising at least one plate member attached to the plate portion of the conducting layer correspondingly.

2. The high-frequency vertical spring probe card structure of claim 1, wherein each of the probes is formed by electroplating through Lithographie GaVanoformung Abformung (LIGA) technology or formed as a multi-layer micro-probe by Micro-Electro-Mechanical System (MEMS) process.

3. The high-frequency vertical spring probe card structure of claim 1, wherein the conducting layer is made of conductive material including at least one of conductive metal and conductive alloy.

4. The high-frequency vertical spring probe card structure of claim 1, wherein the insulating layer is made of non-conductive material including electrical insulation material.

5. The high-frequency vertical spring probe card structure of claim 1, wherein the resilient portion of the probe body of the conducting layer is curved.

6. The high-frequency vertical spring probe card structure of claim 1, wherein the resilient portion of the probe body of the conducting layer has at least one force restricting protrusion.

7. The high-frequency vertical spring probe card structure of claim 1, wherein the plate portion of the probe body of the conducting layer is capable of reinforcing the resilient portion.

8. The high-frequency vertical spring probe card structure of claim 1, wherein the conducting layer and the insulating layer of each probe are separated by each other.

9. The high-frequency vertical spring probe card structure of claim 1, wherein each of the probes comprises a plurality of conducting layers and a plurality of insulating layers separated by each other so as to form a multi-layer stack structure.

10. The high-frequency vertical spring probe card structure of claim 8, wherein the conducting layer comprises a plurality of first contact ends or a plurality of second contact ends contacting one single solder ball.
